(19) United States
(12) Patent Application Publication
(10) Pub. No.: US 2018/0059440 A1
(43) Pub. Date: Mar. 1, 2018

(54) SYSTEMS AND METHODS FOR ACTIVE PHOTONIC DEVICES USING CORRELATED PEROVSKITES

(71) Applicant: THE TRUSTEES OF COLUMBIA UNIVERSITY IN THE CITY OF NEW YORK, NEW YORK, NY (US)

(72) Inventors: Nanfang Yu, Fort lee, NJ (US); Zhaoyi Li, New York, NY (US)

(73) Assignee: THE TRUSTEES OF COLUMBIA UNIVERSITY IN THE CITY OF NEW YORK, NEW YORK, NY (US)

(21) Appl. No.: 15/689,884

(22) Filed: Aug. 29, 2017

Related U.S. Application Data
(60) Provisional application No. 62/380,792, filed on Aug. 29, 2016.

(51) Int. Cl. G02F 1/00; G02F 1/15; G02F 1/153; G02F 1/29; G11C 13/04

(52) U.S. Cl. CPC G02F 1/0018; G02F 1/1523; G02F 1/1533; G02F 1/29; G11C 13/048; G02F 2201/122; G02F 2203/01; G02F 2203/11; G02F 2202/30; G02F 2203/10; G02F 2001/1519

(57) ABSTRACT

Active photonic devices based on correlated perovskites are disclosed. Systems and methods using such active photonic devices are also disclosed. In one example, a smart window including an active photonic device is disclosed. In another example, a variable emissivity coating including an active photonic device is disclosed. In yet another example, an optical memory device including an active photonic device is disclosed. In a further example, an optical modulator including an active photonic device is disclosed. In an additional example, a tunable optical filter including an active photonic device is disclosed. In an additional example, a directional optical coupler including an active photonic device is disclosed.

### CROSS-REFERENCE TO RELATED APPLICATIONS

This application claims priority to U.S. Provisional Patent Application Ser. No. 62/380,792, filed on Aug. 29, 2016, which is incorporated by reference herein in its entirety.

### STATEMENT REGARDING FEDERALLY-SPONSORED RESEARCH

This invention was made with government support under Grant No. D15AP00111 awarded by the Defense Advanced Research Projects Agency; Grant No. N00014-16-1-2442 awarded by the Office of Naval Research; Grant No. FA9550-14-1-0389 awarded by the Air Force Office of Scientific Research (through a Multidisciplinary University Research Initiative program, and Grant No. FA9550-12-1-0189), Grant No. ECCS-1307948 awarded by the National Science Foundation, and Grant Nos. W911NF-16-1-0042 and W911NF-14-1-0669 awarded by the Army Research Office. The government has certain rights in the invention.

### BACKGROUND

The disclosed subject matter relates to active photonic devices, including techniques for making such devices using correlated perovskites.

Active photonic devices can include, but are not limited to tunable color filters, broadband/narrowband optical modulators, smart windows, variable emissivity coatings and integrated photonic devices. For example, optical modulators are typically based on weak nonlinear electro-optic phenomena, such as Pockels effect, optical Kerr effect, and plasma-dispersion effect. Such devices can require either high operation voltages or large device footprints to achieve large modulation depth, and as such, can be unsuitable for device miniaturization and large-scale integration in modern photonic systems. A small electro-optic effect can be amplified to realize large optical modulation in a narrow spectral range by using high-quality-factor optical resonators. For example, fast telecomm electro-optic modulators can be created based on free carrier injection in silicon microresonators.

Large changes in complex refractive indices can be induced in thin-film materials, such as indium tin oxide and graphene, using field effect. However, a significant refractive index change can only occur over small volumes, and nanophotonic structures are often needed to enhance light-material interactions. Electrochromic materials, such as transition metal oxides and conjugated conducting polymers, can show large and reversible changes of color during electrochemical redox reactions. However, the change of optical refractive indices can be diminishingly small as the wavelength increases. An exemplary electrochromic material, WO₃, can provide large modulation of light in the visible and near-infrared, but the modulation depth in the long-wavelength mid-infrared, e.g., λ=8-20 μm, can be limited. Similarly, organic electro-chromic materials can provide low optical modulation in the mid-infrared, due at least in part to various molecular vibrational transitions in the organic molecules.

Phase-change materials, such as chalcogenide alloys, have been used in rewritable CDs, DVDs, and Blu-ray discs, can be switched between amorphous and crystalline states by laser or electrical current pulses with controlled duration and intensity. This material system can thus be used to create multi-level, and non-volatile memory in telecomm integrated photonic circuits, high-resolution solid-state displays, and optically reconfigurable planar optical components. However, chalcogenide alloys can have large absorption coefficients in the visible, and as such, can be unsuitable for modulating visible light.

In the materials systems described above, optical-refractive-index changes can either have low magnitude, or significant refractive index changes can only occur within a narrow wavelength range or over a small spatial volume. Accordingly, there remains an opportunity for improved actively tunable materials, and device architectures using such materials, to dynamically control light with larger modulation depth and increased spectral range, at faster speed, and using less power.

### SUMMARY

The disclosed subject matter provides a smart window, including a transparent material and an active photonic device disposed along the transparent material. The active photonic device can include a thin film of perovskite material disposed proximate the transparent material, a proton barrier disposed proximate the thin film, a proton reservoir disposed proximate the proton barrier, and a metal grating disposed proximate the proton reservoir.

In addition, a variable emissivity coating is disclosed, including a metallic substrate, an electrically-insulative layer disposed proximate the metallic substrate, and an active photonic device disposed proximate the electrically-insulative layer. The active photonic device can include a thin film of perovskite material.

Also, an alternate variable emissivity coating is disclosed including a bottom electrode, an electrolyte layer disposed over the bottom electrode, a plasmonic metasurface layer disposed over the electrolyte layer, a layer of perovskite material disposed over the plasmonic metasurface, and a top cover layer.

Furthermore, an optical memory device is disclosed, including an active photonic device. The active photonic device can include a substrate, a membrane disposed proximate and suspended by the substrate, a thin film of perovskite material disposed proximate the membrane, and a metal grating disposed proximate the thin film.

The disclosed subject matter also includes a metasurface modulator, including a mirror, an insulating layer disposed proximate the mirror, a thin film of perovskite material disposed proximate the insulating layer, and an aperture antenna disposed proximate the thin film.

Finally, a solid-state electro-optic modulator is disclosed including a substrate, a thin film of perovskite material disposed proximate the substrate, a solid polymer electrolyte disposed proximate the thin film, and an electrode disposed proximate the solid polymer electrolyte.

### BRIEF DESCRIPTION OF THE DRAWINGS

FIGS. 1A-1F are diagrams illustrating electron-doping-induced phase transition of one exemplary samarium nickelate material (SmNiO₃, or SNO) and accompanying measurements (FIG. 1F) according to the disclosed subject matter.

FIGS. 2A-2E are diagrams illustrating exemplary techniques for constructing active photonic devices and triggering the phase transition of SNO according to the disclosed subject matter.

FIGS. 3A-3H are diagrams illustrating broadband tuning in the visible, near-infrared, and mid-infrared of devices based on thin-film SNO according to the disclosed subject matter

FIGS. 4A-4C are photos illustrating pristine SNO and electron-doped SNO according to the disclosed subject matter.

FIGS. 5A-5F are diagrams illustrating broadband tuning of near-infrared and mid-infrared transmissivity and reflectivity using thin-film SNO patterned with a Pt grating according to the disclosed subject matter.

FIGS. 6A-6F are diagrams illustrating an exemplary embodiment of an active device (FIG. 6A) based on thin-film SNO that provides dynamically tunable coloration in the visible spectrum (FIGS. 6B-6F) according to the disclosed subject matter.

FIGS. 7A-7E are diagrams illustrating another exemplary embodiment of an active device based on thin-film SNO that provides dynamically tunable coloration in the visible spectrum according to the discloses subject matter.

FIGS. 8A-8C are diagrams illustrating another exemplary embodiment of an active device based on thin-film SNO that provides dynamically tunable coloration in the visible spectrum according to the disclosed subject matter.

FIGS. 9A-9F are diagrams illustrating electrically controllable solid-state electro-optic modulators (FIG. 9A) based on thin-film SNO and measurements (FIGS. 9B-9F), including infrared reflectance spectra (FIG. 9B) and temporal response of the device (FIGS. 9C-9F) according to the disclosed subject matter.

FIGS. 10A-10I are diagrams illustrating narrowband tuning of infrared reflectivity in devices consisting of plasmonic metasurfaces and SNO thin films according to the disclosed subject matter.

FIGS. 11A-11D are diagrams illustrating the performance of metasurface-based devices referenced in FIG. 10A according to the disclosed subject matter.

FIGS. 12A-12B are diagrams illustrating measured reflectance spectra of metasurface-based devices as referenced in FIG. 10A according to the disclosed subject matter.

FIGS. 13A-13B are diagrams illustrating an exemplary embodiment of a smart window based on the phase-transition material SNO and the simulated transmission spectra according to the disclosed subject matter.

FIGS. 14A-14E are diagrams illustrating another exemplary embodiment of a smart window based on the phase-transition material SNO and accompanying simulation results according to the disclosed subject matter.

FIGS. 15A-15F are diagrams illustrating an exemplary embodiment of a variable emissivity coating based on a plasmonic hole array (FIGS. 15A-15D) and measured spectra of the device (FIGS. 15E-15F) according to the disclosed subject matter.

FIGS. 16A-16B are diagrams illustrating tunable emissivity spectra measured from a device consisting of a plasmonic hole array and phase-transition material SNO according to the disclosed subject matter

FIGS. 17A-17F are diagrams illustrating another exemplary embodiment of variable emissivity coating based on an array of cross-shaped plasmonic apertures (FIGS. 17A-17D) and measured spectra of the device (FIGS. 17E-17F) according to the disclosed subject matter.

FIGS. 18A-18C are diagrams illustrating another exemplary embodiment of variable emissivity coating (FIG. 18A) based on the binary metasurface design (FIG. 18C) and the measured spectra (FIG. 18B) according to the disclosed subject matter.

FIGS. 19A-19C are diagrams illustrating an exemplary embodiment of a directional coupler based on the phase-transition material SNO (FIG. 19A) and simulated device performance (FIGS. 19B-19C) according to the disclosed subject matter.

FIG. 20 is a diagram illustrating a device to realize spatial modulation of optical properties that can be used for optical memory and spatial light modulation according to the disclosed subject matter.

### DETAILED DESCRIPTION

The disclosed subject matter provides systems and methods for creating active photonic devices using correlated perovskites. Strongly correlated perovskites can have a widely tunable electronic structure that can host a variety of phases. Nickelates, for example and without limitation, can undergo electric-field-tunable phase transitions with significant changes in the optical properties. A large and non-volatile optical refractive index change can be associated with an electron-doping induced phase transition of perovskite nickelates, for example but not limited to EuNiO₃, SmNiO₃, NdNiO₃, and LaNiO₃, which can be utilized to achieve strong optical modulation.

For example, large electrical modulation of light over a broad wavelength range, from the visible to the mid-infrared, i.e., λ=400 nm to 17 μm, can be provided using thin-film SmNiO₃ (SNO). SmNiO₃ can be integrated into plasmonic metasurface structures, and as such, modulation of a narrow band of light that resonantly interacts with the metasurfaces can be achieved. SmNiO₃ and solid polymer electrolytes can be integrated to create solid-state electro-optic modulators. Correlated perovskites with tunable and non-volatile electronic phases can thus provide a platform for active photonic devices, such as tunable color filters, electro-optic modulators, electrically programmable optical memories, smart windows for controlling sunlight, and variable emissivity coatings for infrared camouflage and thermoregulation.

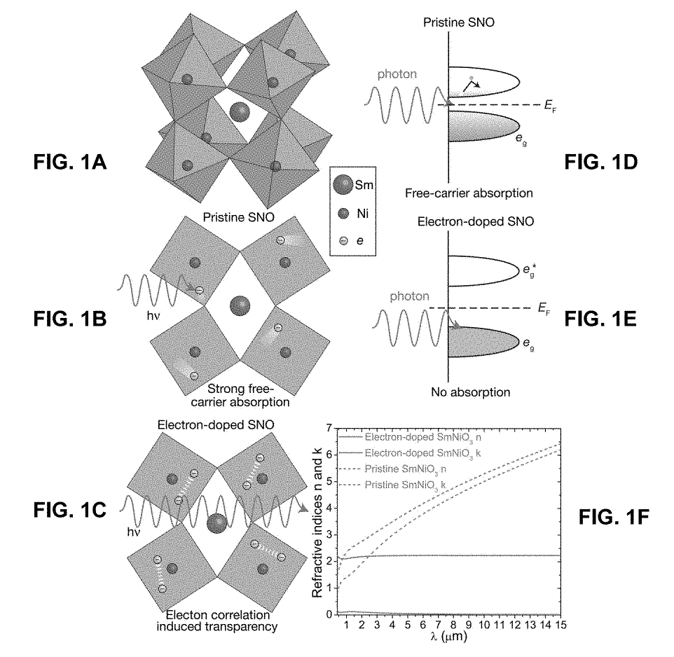

Referring to FIGS. 1A-1F, the electronic phase diagram of correlated perovskite nickelates is sensitive to orbital occupancy of electrons. For example and without limitation, SNO can exhibit reversible modulation of electrical resistivity greater than eight orders of magnitude and an order of magnitude change in optical band gap at room temperature during an electron-doping-induced phase transition. FIG. 1A illustrates a perovskite structure of SNO. Each vertex of the octahedra represents one oxygen atom. FIG. 1B illustrates that in pristine SNO electrons are itinerant because of the single occupancy of the Ni e_{g} orbital, and as such, can cause strong free-carrier absorption of light. FIG. 1C illustrates that each NiO₆ octahedra can be doped with one more electron, and strong Coulomb repulsion can initiate electron localization and suppress the interaction between electrons and photons. FIG. 1D illustrates that the conduction band of pristine SNO is populated with free electrons, which lead to strong free-carrier absorption. FIG. 1E illustrates that strong electron correlation in doped SNO opens a wide bandgap and can reduce or eliminate free electrons. In FIGS. 1D-1E, the horizontal axis represents the density of states, and the vertical axis represents energy; e_{g}* in FIG. 1E represents the antibonding state of the e_{g} orbital. FIG. 1F illustrates complex refractive indices (n and k) obtained experimentally. Pristine SNO has high electrical conductivity and is optically opaque. Electron-doped SNO is electrically insulating and optically transparent. The electron doping process (as embodied herein, doping concentration on the order of 0.1-1 carriers per unit cell, or ≈10²¹-10²² cm⁻³) can be induced by any suitable approach, for example and without limitation, gas phase, liquid phase, and solid-state dopant injection.

Specifically, in some embodiments pristine SNO, Ni³⁺ can have an electron configuration of t₂_{_{g}}⁶e_{g}¹, and the single e_{g} electron can introduce strong optical losses through free carrier absorption, as shown in FIG. 1B, which can be characterized by a large imaginary part, k, of the complex refractive index, illustrated in FIG. 1F. An extra electron can be acquired, and the fourfold degenerate (including spin) e_{g} manifold is occupied by two electrons. The strong intra-orbital Coulomb repulsion between e_{g} electrons can open a band gap as large as 3 eV and can substantially suppress the free carrier absorption, as shown in FIG. 1C. In this manner, SNO can be transformed into an optically transparent dielectric with n≈2.2 and k close to zero throughout the visible, near-infrared, and mid-infrared, as shown in FIG. 1F. These changes in the optical properties upon electron-doping can also be understood on the basis of the change in the density of states near the Fermi level, as illustrated in FIGS. 1D-1E.

Moreover, correlated perovskites, SNO being one example, offer a combination of desirable properties and can have a large impact on transformative technologies. For example, i) the phase transition of the material is based on electron doping/extraction, which is independent of temperature constraints, and is well-suited for creating electric-field tunable solid-state devices operating at room temperature; ii) there is no crystal symmetry change during the phase-transition process, at least within the detection capability of X-ray and electron diffraction. This is unlike the structural symmetry breaking seen in the thermal phase transitions of nickelates and VO₂, or switching between amorphous and crystalline states in phase-change chalcogenide alloys. This feature allows for fast switching between the two states of SNO, limited by the speed of carrier injection and removal, and electron pairing and unpairing processes; iii) there is a substantial change in optical refractive indices over an unprecedented broad spectrum from the visible to the long-wavelength mid-infrared (λ=400 nm to 16 μm), as shown in FIG. 1F; iv) the transparent and opaque states are non-volatile (i.e., states are stable without the bias voltage), which is well-suited for low power consumption applications; v) continuous and reversible tuning between opaque and transparent states can be achieved, and vi) high quality thin films (i.e., singe-crystal and polycrystalline) can be reliably synthesized (e.g., co-sputtering of Sm and Ni followed by annealing in O₂) and are stable in ambient conditions and in liquid water.

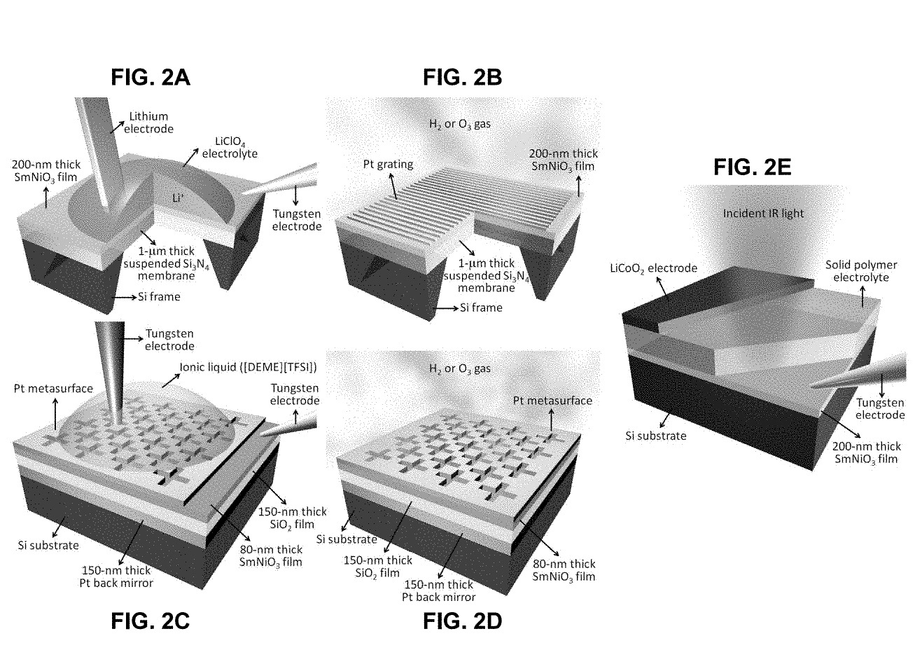

Tunable photonic devices can be provided based on several different architectures and utilizing a range of techniques to induce the doping-driven phase transition of SNO, as shown for example in FIGS. 2A-2E and discussed further herein. Specifically, techniques illustrated in FIGS. 2A and 2C are based on using liquid electrolytes. Techniques illustrated in FIGS. 2B and 2D are based on gas phase dopant injection, and techniques illustrated in FIG. 2E are based on using solid-state electrolytes. Exemplary photonic devices provided using the techniques according to the disclosed subject matter (shown in FIGS. 2A-2E), without limitation, include: i) devices based on thin-film SNO providing large and broadband tuning of optical transmissivity, reflectivity, and emissivity; such devices have potential applications, without limitation, in tunable color filters, smart windows, and variable emissivity coatings; ii) devices based on plasmonic metasurfaces integrated with thin-film SNO providing large tuning of transmissivity or reflectivity over a narrow band of wavelengths; such devices have potential applications, without limitation, in optical modulators and optical memories. For example, techniques to trigger the phase transition of perovskite materials according to the disclosed subject matter, without limitation, include: i) using liquid electrolytes containing ions, such as protons (H⁺) and lithium ions (Li⁺), as shown in FIGS. 2A, 2C; ii) using hydrogenation and de-hydrogenation (i.e., annealing the device in H₂ and in O₂ or O₃) in the presence of suitable catalysts, such as platinum (Pt), as shown in FIGS. 2B, 2D; iii) using solid materials containing ions, such as solid polymer electrolytes and ion-conducting ceramics (e.g., yttrium-doped barium zirconate (BYZ), and yttria-stabilized zirconia (YSZ)), as shown in FIG. 2E.

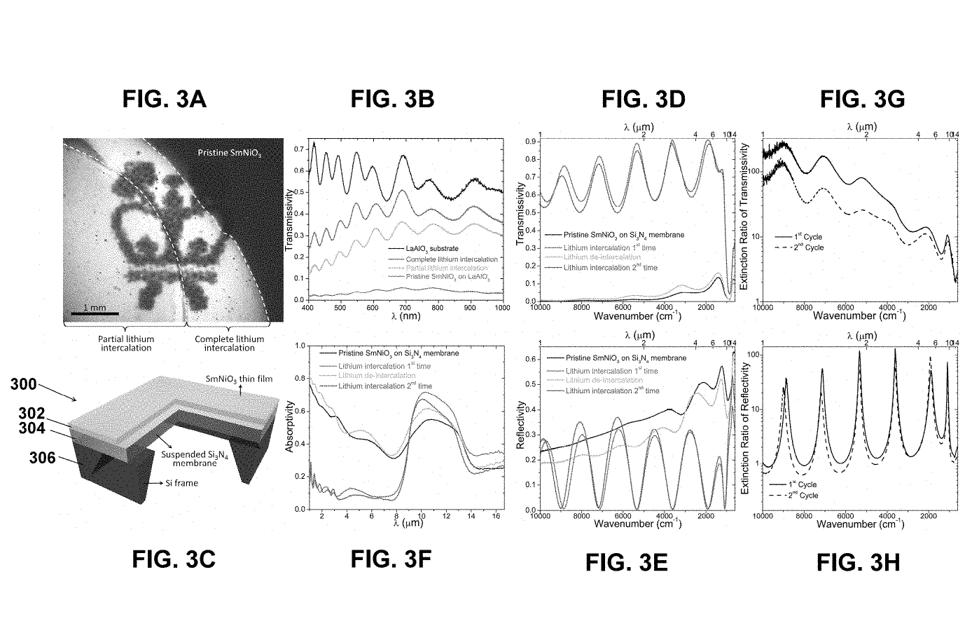

Referring now to FIGS. 3A-3H, broadband tuning through the visible, near-infrared, and mid-infrared using thin-film SNO is illustrated. The phase transition of SNO can be realized by lithium intercalation and de-intercalation, as described further herein. An electrolyte containing lithium ions is added on the surface of SNO, and a voltage is applied between SNO and a lithium electrode to drive ion transport. The lithium ions adsorbed on the surface and doped in SNO can facilitate the incorporation of electrons, which trigger the phase transition of SNO. A voltage with reverse polarity can pull lithium ions back to the electrolyte, and the SNO film can thereby be converted back to the pristine state.

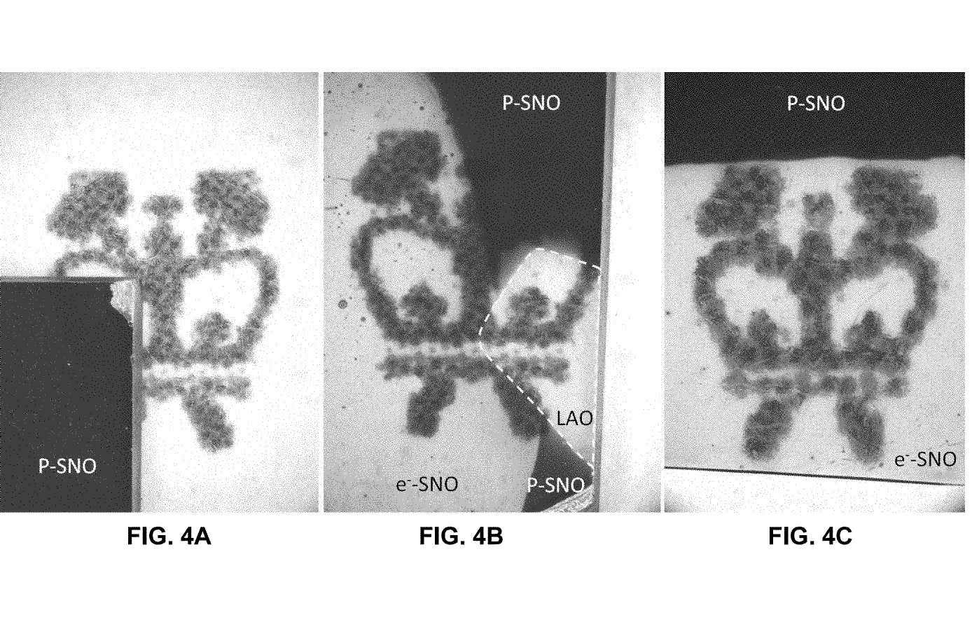

FIG. 3A is an optical image illustrating the operation of an exemplary tunable photonic device placed on top of a logo (e.g., Columbia Engineering logo). The device includes an 80-nm SNO thin film deposited on a 500-μm LaAlO₃ substrate. The large tuning of visible light transmission is illustrated by different degrees of transparency corresponding to SNO at its intrinsic state and at different stages of electron doping. Additional exemplary optical images of the photonic device placed on top of the logo are shown in FIGS. 4A-4C for purpose of illustration and not limitation. FIGS. 4A-4C illustrate that pristine SNO is opaque (see FIG. 4A), whereas electron-doped SNO exhibits improved transparency (see FIGS. 4B-4C)).

FIG. 3B illustrates measured visible and near-infrared transmission spectra taken from different regions of FIG. 3A. The transmission spectra illustrates that the averaged transmissivity of the device with intrinsic SNO over the wavelength range of 400-1000 nm is about 0.04. When SNO is in the electron-doped state (embodied herein as complete lithium intercalation), the averaged transmissivity can increase drastically to about 0.39, where optical losses are mostly caused by the LaAlO₃ substrate. The tuning of transmissivity averaged in the visible (λ=400-700 nm) is approximately 0.35.

FIG. 3C is a schematic diagram of another exemplary tunable photonic device 300 including a 200-nm SNO film 302 deposited on a 1-μm suspended Si₃N₄ membrane 304. As embodied herein, membrane 304 is disposed on a Si frame 306. FIGS. 3D-3F illustrate measured transmission, reflection, and absorption spectra, respectively, of device 300, showing good reversibility and repeatability of the device performance in the near-infrared and mid-infrared. The spectra are obtained, as embodied herein, after removing the electrolyte containing lithium ions at the end of each electrochemical reaction. FIG. 3D illustrates that the transmissivity of the device with pristine SNO is below 0.05 in the near-infrared (wavenumber ν, from 4000 to 10000 cm⁻¹, or wavelength λ, from 1 to 2.5 μm) and below 0.17 in the mid-infrared (ν=600-4000 cm⁻¹, or λ=2.5-16.7 μm). After electron doping of SNO, however, the device becomes optically transparent with transmissivity approximately 0.7, except for, as embodied herein, a pronounced dip around ν=1000 cm⁻¹ or λ=10 μm in FIG. 3D, which is due to optical absorption as a result of the phonon resonance in Si₃N₄. FIGS. 3G-3H illustrate the extinction ratio of optical transmission and reflection, respectively, of device 300 during two representative cycles of phase transition. The optical transmissivity can be tuned by a factor as large as about 270 at ν=9000 cm⁻¹ or λ=1.1 μm and by a factor larger than 10 at ν>2000 cm⁻¹ or λ<5 μm.

Referring still to FIG. 3, both the transmission and reflection spectra can be superimposed with Fabry-Pérot fringes, indicative of thin-film interference, when SNO is in the transparent state. Anti-reflective conditions (e.g., reflectivity<0.01) can be obtained at six different wavelengths, as shown for example in FIG. 3E, and tuning of optical reflectivity at these wavelengths can reaches maxima, as shown for example in FIG. 3H. Optical absorptivity, represented herein as (1−reflectivity−transmissivity), can be tuned for wavelengths smaller than 8 μm, as shown for example in FIG. 3F. This implies that the device 300 is capable of providing tunable thermal emission at λ<8 μm as Kirchhoff's law of thermal radiation states that wavelength-specific emissivity equals to absorptivity.

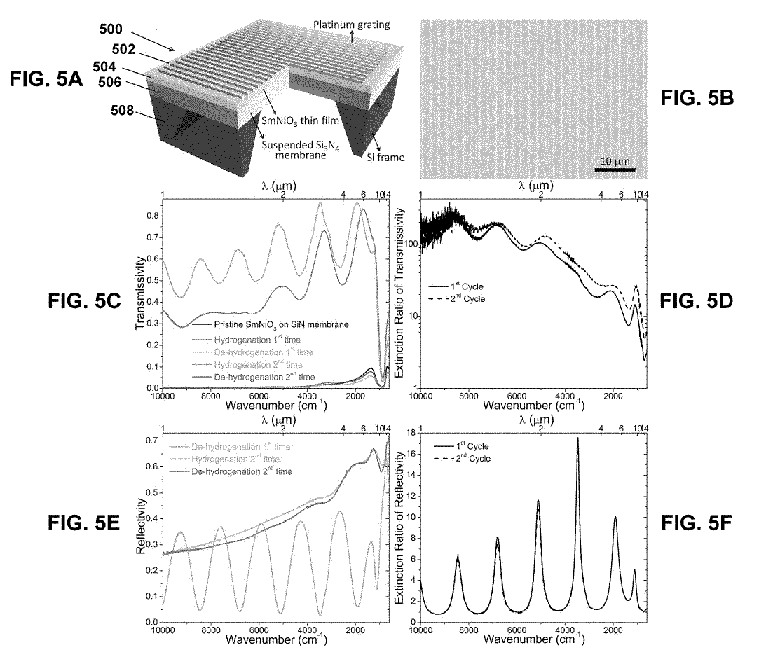

Similar results to those shown in FIGS. 3A-3H can also be obtained in SNO thin films, where the phase transition is induced by hydrogenation/de-hydrogenation (or proton intercalation/de-intercalation). Referring now to FIGS. 5A-5F, broadband tuning of near-infrared and mid-infrared transmissivity and reflectivity using thin-film SNO patterned with a Platinum (Pt) grating is illustrated, where the phase transition of SNO is realized by annealing the device in H₂ and O₃. FIG. 5A is a schematic diagram of device 500. The device 500 includes a Pt grating 502 patterned on an SNO film 504, which is disposed on a suspended Si₃N₄ membrane 506, as best shown in FIGS. 5A-5B. As embodied herein, membrane 506 is disposed on a Si frame 508. The Pt grating 502 serves as a catalyst for the hydrogenation process, in which H₂ molecules can dissociate to atomic hydrogen, and can further split into protons and electrons that can be incorporated into the SNO film 504. As embodied herein, device 500 can be annealed in O₃ to reverse the phase transition. FIG. 5B is an optical image of fabricated structure of device 500. Bright vertical lines represent Pt grating fingers with a periodicity of 2 μm. FIG. 5C illustrates measured transmission spectra of device 500. FIG. 5D illustrates the extinction ratio of optical transmission during two representative cycles of SNO phase transition. FIG. 5E illustrates measured reflection spectra of device 500. FIG. 5F illustrates the extinction ratio of optical reflection during two cycles of SNO phase transition. Measured transmissivity is below 0.1 over the entire infrared spectrum when SNO is in its pristine or de-hydrogenated state, and can be up to 0.85 for hydrogenated SNO, as shown for example in FIG. 5C. The optical transmissivity can be tuned by a factor larger than 20 for λ<5 μm, as shown for example in FIG. 5D. Large tuning of optical reflection occurs at several wavelengths corresponding to Fabry-Pérot resonances, as shown for example in FIGS. 5E-5F.

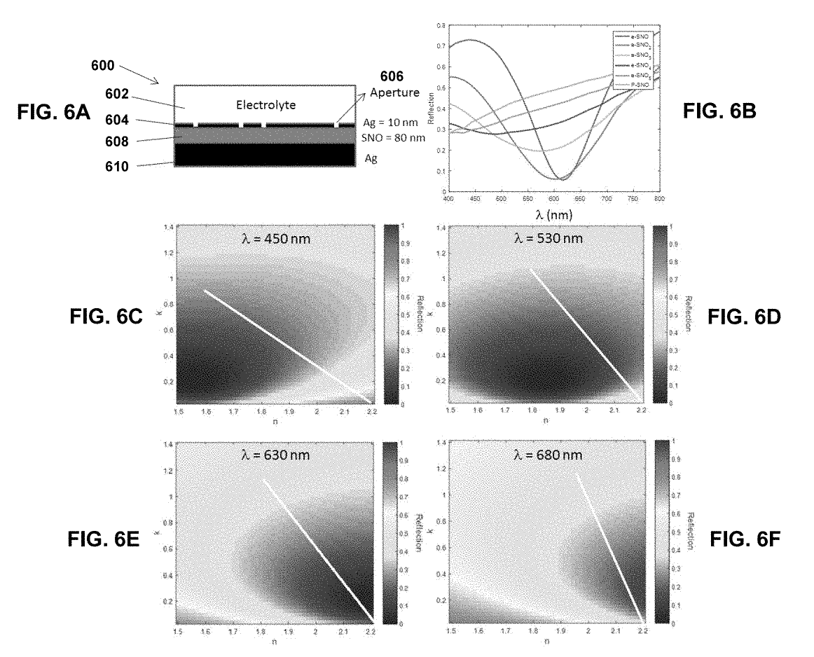

The large optical tunability of SNO in the visible spectral range can be used to create thin-film devices that provide dynamically tunable coloration. One design of such device 600 is shown in FIG. 6A. It consists of a silver (Ag) substrate 610, an 80-nm SNO thin film 608, a 10-nm semi-transparent Ag cover layer 604, and an electrolyte layer 602 on the top of the device (for triggering phase transition of SNO via electrochemical reactions). The Ag cover layer 604 can be patterned with apertures or slits 606 to allow SNO 608 to have access to ions and electrons in the electrolyte 602. FIG. 6B illustrates calculated reflectance spectra of the device, showing that when SNO is in the pristine state (P-SNO), the stack has a warm coloration, whereas the coloration becomes colder when more electrons are doped into the SNO thin film (e-SNO). A transfer matrix formulism and realistic complex refractive indices of materials are used to calculate the reflectance spectra. FIGS. 6C-6F illustrate calculations showing the evolution of reflectance at four wavelengths (λ=450 nm, 530 nm, 630 nm, and 680 nm) in the visible spectrum when the complex refractive indices of SNO (n and k) change during the phase transition process. It is assumed that the changes of n and k follow a straight line (indicated by the white lines) in the n-k map.

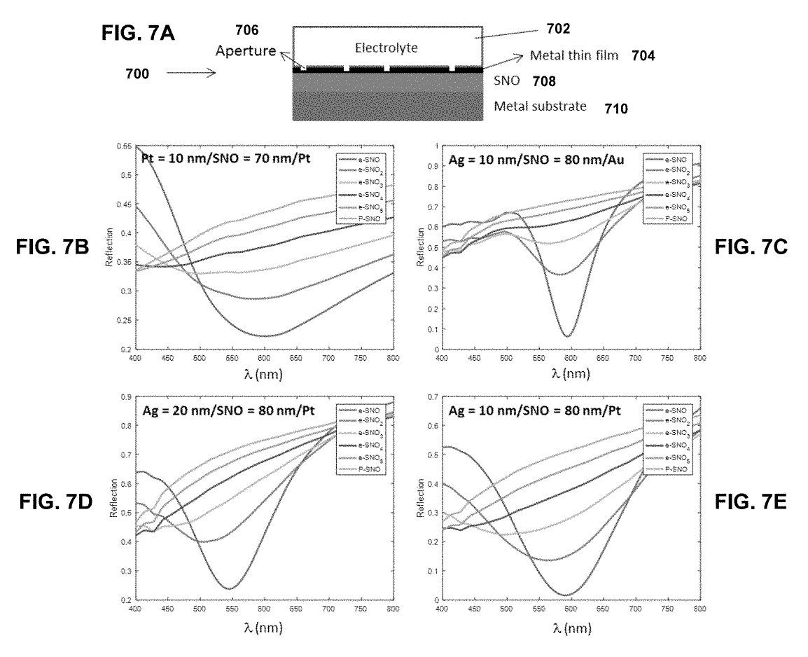

FIGS. 7B-7E are diagrams illustrating calculated reflectance spectra for a few devices 700 of similar configurations as in FIG. 6A when the type and thickness of the top metal layer 704, SNO thickness, and type of the metal substrate 710 are varied. All examples indicate strong tuning of visible coloration. FIG. 7A is the schematic showing the similar device configuration as shown in FIG. 6A and FIGS. 7B-7E illustrate calculated reflectance spectra of the device when SNO is tuned from the pristine state (P-SNO) to the electron-doped state (e-SNO) with varying degrees of electron doping.

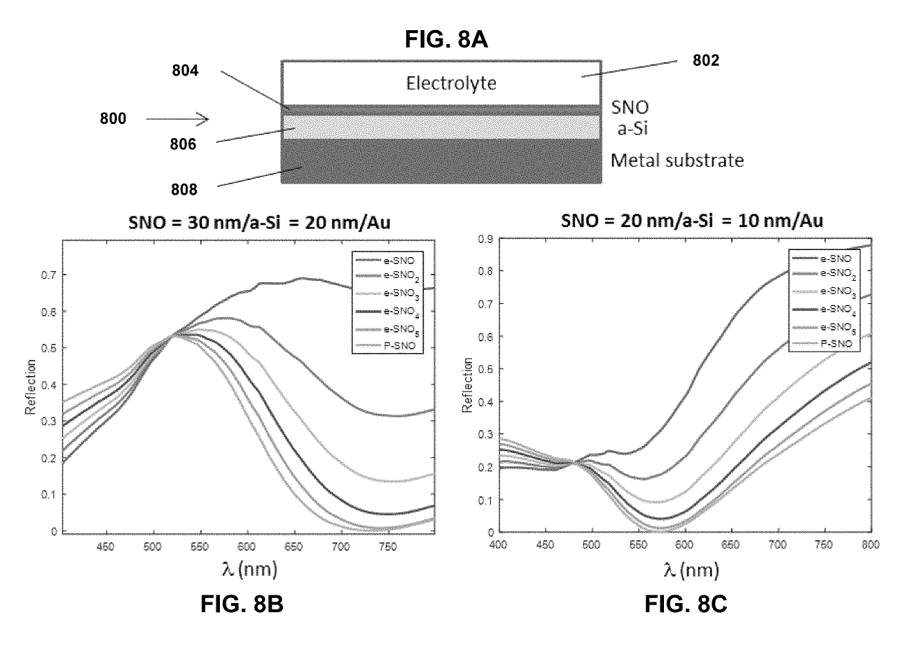

Another device 800 to realize tunable coloration by exploring Fabry-Pérot resonances in thin-film stacks is shown in FIG. 8A. The device consists of an electrolyte 802, a SNO thin film 804, an amorphous silicon (a-Si) layer 806, and a metal substrate 808. The SNO thin film 804 has direct access to the top electrolyte 802. FIGS. 8B-8C are diagrams illustrating calculated reflectance spectra of the device 800 in FIG. 8A, showing that the coloration becomes warmer when SNO undergoes phase transition from the pristine state to the electron-doped state.

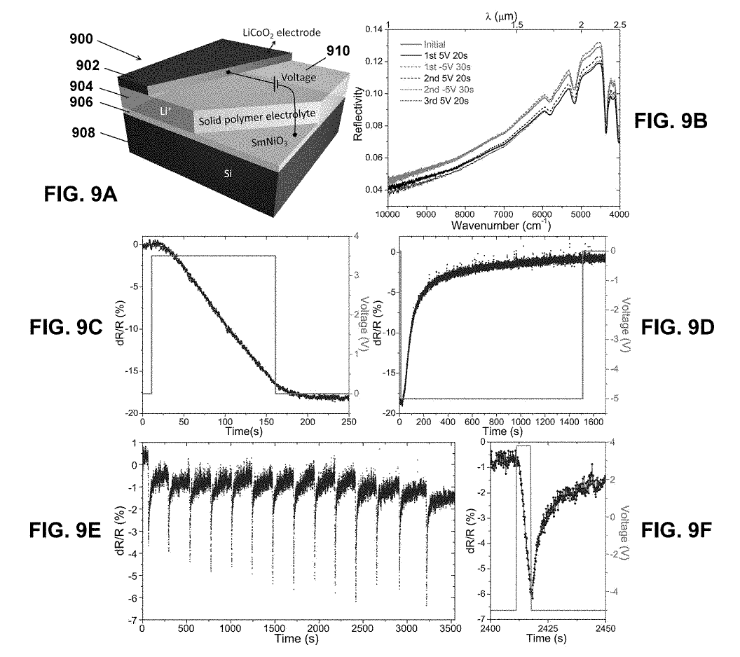

With reference to FIGS. 9A-9F, electrically controllable solid-state electro-optic modulators based on SNO are illustrated. FIG. 9A is a schematic of an exemplary electro-optic modulator 900 including a 200-nm SNO film 906, a solid polymer electrolyte 904 containing lithium ions and providing high ionic conductivity, and a LiCoO₂ electrode 902. As embodied herein, the SNO thin film 906 is deposited on a Si substrate 908. The lithium ions can be provided by bis(trifluoromethane)sulfonamide lithium salt (LiTFSI), and the polymer can be based on poly(ethylene glycol) (PEG). The solid polymer electrolyte 904 can transport lithium ions between the LiCoO₂ electrode 902 and SNO thin film 906 to induce phase transition of the latter. Certain solid polymer electrolytes can be chosen, as described further herein, at least in part because of high ionic conductivity to accelerate lithium intercalation/de-intercalation cycles and resistance to lithium dendrite formation to ensure safe operation of the device for many cycles.

FIG. 9B illustrates measured infrared reflectance spectra during repeated phase-transition cycles of SNO. Reversible modulation of reflectivity dR/R=10%-25% can be measured in the wavelength range of λ=1-2.5 μm on an area of the solid-state device without the top LiCoO₂ electrode 902, as shown in FIG. 9B.

Voltages 910 of +3.5 and −5 V can be applied to drive lithium intercalation and de-intercalation processes, respectively, and as shown for example in FIGS. 9C-9D, about 18% modulation of dR/R can be measured at the telecommunications wavelength of 1.55 μm. As embodied herein, bulk phase change of 200-nm SNO occurred in about 120 s for the intercalation process and about 280 s for the de-intercalation process (as embodied herein, time constant represents the duration in which relative reflectivity dR/R changes from 0% to 80% of its peak value).

Partial phase transition of the SNO thin film 906 can be allowed (as embodied herein, phase transition only occurs near top layers of the film), and the response time can be substantially reduced, while the optical modulation strength can decrease correspondingly. For example, as embodied herein, a modulated reflectivity ΔR/R of ≈5.5% at λ=1.55 μm can be achieved when the applied voltage 910 is repeatedly switched between +3.8 and −5 V, as shown for example in FIGS. 9E-9F, and the intercalation time for each cycle can be only approximately 5 s, while the de-intercalation time can be only approximately 23 s. The response time is affected by the diffusion of lithium ions in the solid polymer electrolyte and does not always represent the intrinsic response time of SNO phase transition. The reflectance spectra in FIG. 9B are stable after removal of applied voltage, demonstrating the non-volatility of the devices.

The speed of bulk phase transition is inversely proportional to the total volume of SNO being switched (since the electron doping process can be diffusional in nature beyond the screening length), and ultrathin SNO films can be used to achieve, for example, high-speed optical modulation and high-speed programming suitable for optical memory. However, as the amount of phase-change material is reduced, the magnitude by which light can be modulated decreases. Increasing or maximizing modulation strength while decreasing or minimizing the amount of phase-change materials used can be achieved by integrating SNO into metasurface structures, which consist of 2D arrays of densely packed optical antennas with subwavelength dimensions, and can mediate strong light-material interactions on a 2D plane.

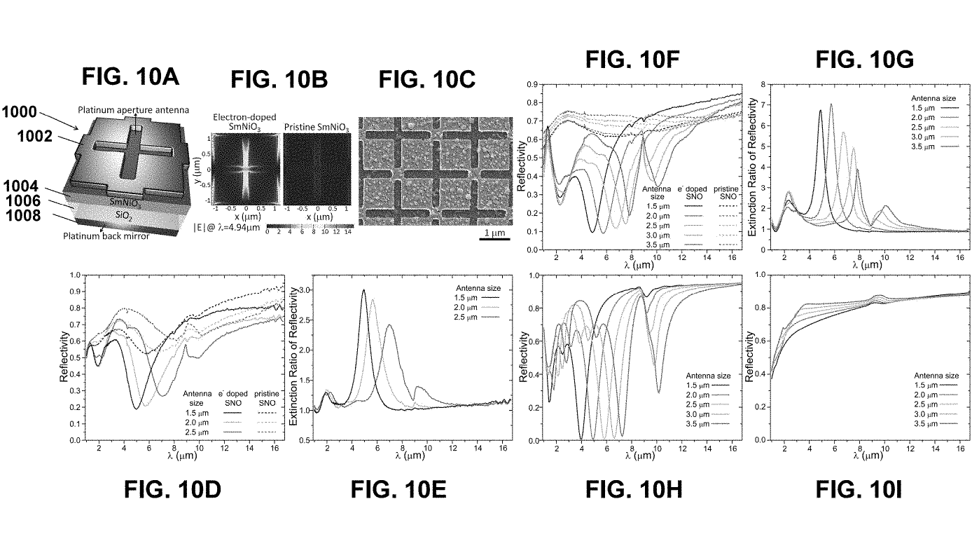

Referring to FIGS. 10A-10I, metasurface structures can be fabricated on SNO thin films, and tuning of reflected light in a narrow band of mid-infrared spectrum can be achieved. FIG. 10A is a schematic of the unit cell of an exemplary device. The unit cell includes a Pt aperture antenna 1002 separated from a Pt mirror 1008 by thin films of SNO 1004 and SiO₂ 1006. FIG. 10B depicts simulations showing optical near-field distributions (embodied herein as |E|) around one aperture antenna. As embodied herein, the antenna is 2 μm×2 μm in size and incident light at λ=4.94 μm is polarized along the x-direction. Strong plasmonic resonance can occur when SNO is doped with electrons, whereas the plasmonic resonance is damped when SNO is in the pristine state.

FIG. 10C is a scanning electron microscope (SEM) image of a portion of device consisting of Pt cross apertures 2 μm×2 μm in size patterned on an SNO thin film. FIG. 10D illustrates measured reflectance spectra of devices, where the phase transition of SNO is induced by ionic liquid gating. FIG. 10E illustrates the extinction ratio of the reflectance spectra in FIG. 10D, showing large tuning of reflectivity over narrow spectral ranges. The spectral location of peak tuning can be determined by the size of aperture antennas. FIG. 10F illustrates measured reflectance spectra of devices, where with the phase transition of SNO is induced by hydrogenation and de-hydrogenation. FIG. 10G illustrates the extinction ratio of the reflectance spectra in FIG. 10F, showing large tuning of reflectivity over narrow spectral ranges. FIGS. 10H-10I depict simulated reflectance spectra when SNO is switched between the electron-doped and pristine states.

When SNO is in the electron-doped state, the plasmonic resonance can produce significant absorption of optical power, because of optical losses in the metallic antenna structure 1002 and in SNO (electron-doped SNO has small but non-zero imaginary part of the complex refractive index), which result in a dip in the reflectance spectra, as shown for example in FIGS. 10D, 10F and 10H. The spectral location of the dip can be controlled by the size of the aperture antennas 1002: longer apertures resonantly interact with light with proportionally longer wavelengths. When SNO is at its pristine state, however, strong optical losses can substantially or completely damp the plasmonic resonance, and as such, the reflectance spectra are featurelessly flat, as shown for example in FIGS. 10D, 10F and 10I.

The resonant interaction between light and the aperture antennas 1002 can lead to substantial tuning within a narrow band of spectrum, as shown for example in FIGS. 10E and 10G, while SNO is switched between the opaque and transparent states. The cross-shaped apertures are chosen in part because of their suitability for use with light having arbitrary states of polarization.

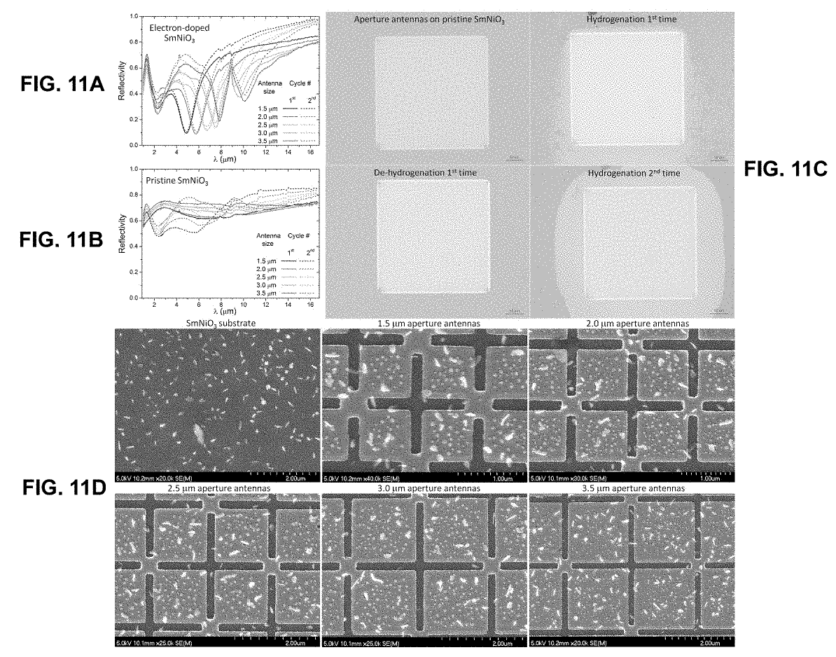

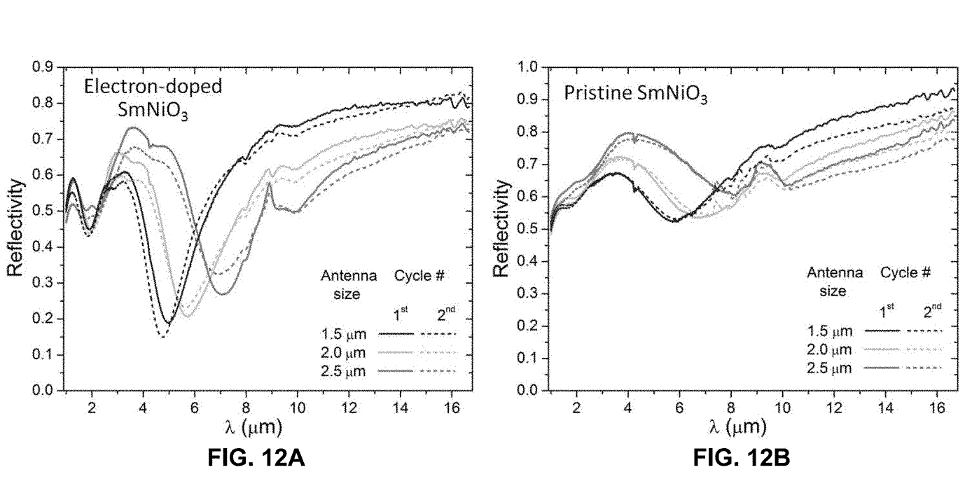

The Pt back mirror 1008 can be used to create image dipoles of the aperture antennas. The near-field coupling between the aperture antennas and their image dipoles can reduce the radiation losses and thus produce narrow spectral features. The narrow spectral feature can allow, for example and without limitation, for tuning of a narrow band of infrared light or optical memory devices that can only be read by light of selected wavelengths. For example and without limitation, as embodied herein, device 1000 patterned with cross apertures 2 μm×2 μm in size can tune optical reflectivity by a factor of 7 at λ=5.7 as shown for example in FIG. 10G, while the tuning of light at λ>8 μm of the same device is minor. FIGS. 11A-11B and 12A-12B show repeatability of device performance during several cycles of SNO phase transition. Phase transition of SNO in FIGS. 11A-11B is induced by hydrogenation and de-hydrogenation, and Phase transition of SNO in FIGS. 12A-12B is induced by ionic liquid gating.

FIG. 11C illustrates optical microscope images of a device going through two phase-transition cycles. The device consists of an array of aperture antennas 1.5 μm×1.5 μm in size patterned on thin films of SNO/SiO₂/Pt. Regions of hydrogenated SNO appear pink in color, and regions of pristine SNO appear green in color. FIG. 11D illustrates SEM images of a bare SNO film and Pt aperture antennas of different sizes patterned on the film.

FIGS. 12A-12B show the measured reflectance spectra of metasurface-based devices referenced in FIG. 10A. Specifically, measured spectra during two representative phase-transition cycles are shown as solid and dashed curves, respectively.

The active photonic devices disclosed herein can be used for various applications such as the creation of smart windows. Smart windows can enhance the energy efficiency of buildings by making good use of light and energy that nature offers. The science and technology of smart windowed have been studied for over three decades; however, smart window technology has not been widely deployed and this is due to a number of challenges. The phase-transition material SNO can help overcome some of the hurdles for the implementation of smart windows.

Specifically, the comparative advantages of SNO-based smart windows are based at least on the following facts: i) smart windows are traditionally based on electrochromic (EC) materials, which are able to change their transparency in response to an applied electrical current or voltage. EC materials have to stay charge neutral, and injection of electrons should be accompanied by insertion of ions, such as H⁺ and Li⁺. Therefore, EC materials have to be nanoporous to facilitate insertion and extraction of ions, which puts stringent requirements on materials growth (e.g., substrate temperature, pressure, oxygen/argon ratio, absence/presence of water vapor, deposition rate, etc.), and the detailed film growth conditions usually play a decisive role for the performance of the EC materials. However, the phase-transition material SNO does not need to be nano-porous. In fact, crystalline SNO thin films grown on lattice matched LaAlO₃ substrates exhibit the largest tunable optical properties. Phase-transition SNO is fundamentally different from conventional EC materials in that it is a strongly correlated electronic material. ii) Tunable complex optical refractive indices offered by conventional EC materials are not sufficiently large for a functioning smart window, often meaning that two complementary EC oxides are employed (e.g., a cathodic EC oxide and an anodic EC oxide that color and bleach at the same time). The reason that the tunability of optical transparency in traditional EC materials is limited is that there is no bandstructure change during the ion/electron insertion/extraction process and that the color change is due to filling of bands of transition metal ions.

The optical phase-transition materials SNO offers much larger tunable complex optical refractive indices than conventional EC materials (see FIG. 1F). This is because of the drastic band structure change of SNO during phase transition as a result of strong electron correlation, which is a collective quantum effect. A single layer of nano-structured SNO thin film will be able to provide sufficiently large tuning of solar transmission in the visible and in the near-infrared.

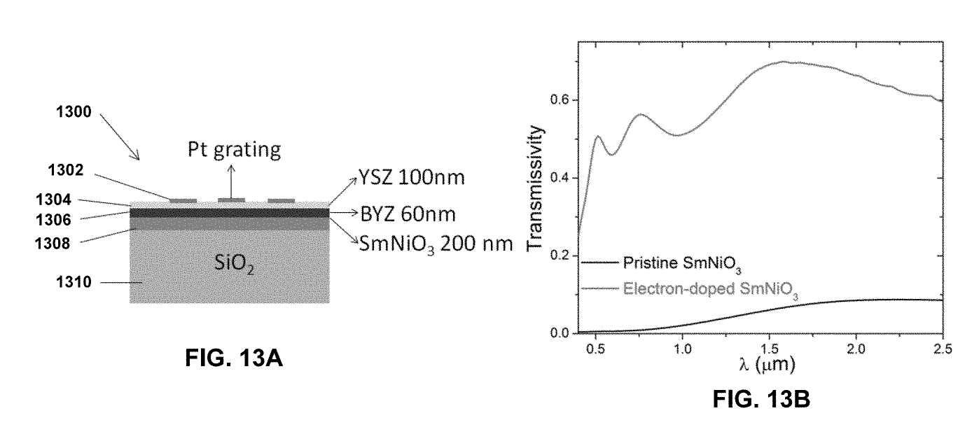

FIG. 13A illustrates one design of a smart window. FIG. 13A is a schematic diagram of an exemplary smart window 1300 in accordance with the disclosed subject matter. For purpose of illustration and not limitation, and as embodied herein, smart window 1300 includes a 200-nm SNO thin film 1308 that is deposited on a transparent material 1310, such as glass or SiO₂. Smart windows 1300 includes also a 60-nm BYZ (yttrium-doped barium zirconate) layer 1306 and a 100-nm YSZ (yttria-stabilized zirconia) layer 1304 deposited on the SNO thin film 1308. A metallic grating 1302, embodied herein as a Pt grating, is patterned on the outermost surface of the smart window 1300. For purpose of illustration and not limitation, as embodied herein, the Pt grating 1302 on the surface has a periodicity of 15 μm. The Pt fingers have a width of 2 μm and a thickness of 50 nm. The device is annealed in H₂ gas, whereby protons and electrons diffuse into the YSZ 1304, BYZ 1306, and SNO 1308 layers assisted by catalyst Pt. At room temperature, BYZ (yttrium-doped barium zirconate) layer 1306 is utilized as a proton reservoir/conductor, and YSZ (yttria-stabilized zirconia) layer 1304 is utilized as a proton insulator. An applied negative or positive voltage can control the migration of protons into and out of the SNO thin film 1308. The migration of protons can control electron doping of SNO, and in this manner, the SNO thin film 1308 can switch between the optically opaque and transparent states.

FIG. 13B is a diagram illustrating simulated transmission spectra of the smart window 1300. When the SNO thin film 1308 is in the pristine state, the smart window 1300 has negligible transmission in the visible spectrum, and as such, will be substantially or completely dark. The transmissivity in the near-infrared is below 0.1. When the SNO thin film 1308 is in the electron-doped state, the smart window 1300 has peak transmissivity of about 0.56 near λ=750 nm in the visible and about 0.7 near 1.6 μm in the near-infrared. The modulation amplitude of transmissivity is about 0.5 across the solar spectrum. In both states, the smart window 1300 can block UV radiation. As shown and described with respect to FIGS. 9A-9F, the phase transition of SNO thin film 1308 can be within one minute, which is comparable to the eye's light-adaptability. Therefore, SNO is suitable for smart window applications.

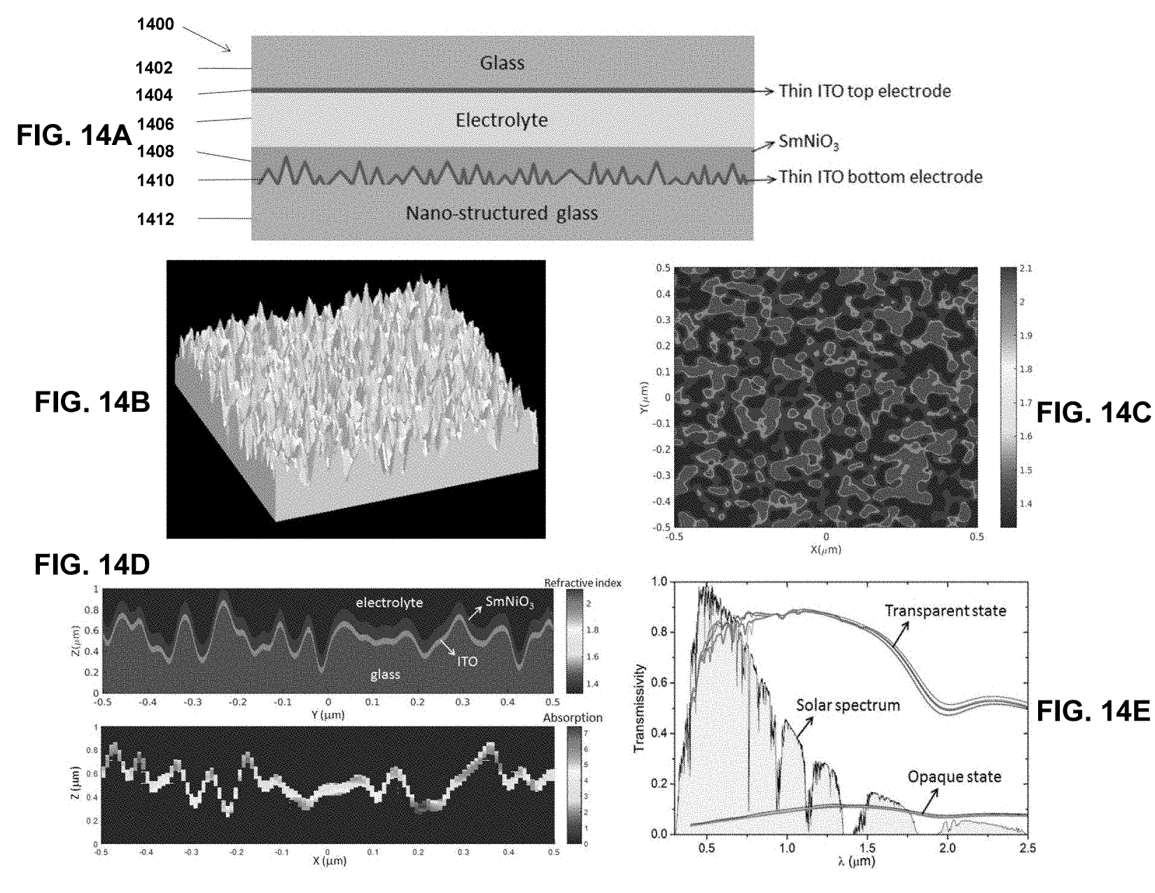

FIG. 14A illustrates an additional design of a smart window. The device 1400 is based on the thin-film battery configuration and consists of a nano-structured SNO thin film 1408. The latter can be realized by etching glass substrates using a non-lithographic anisotropic etching and depositing SNO thin films onto the nano-structured glass 1412, as illustrated in FIG. 14B (e.g., showing the model of the nano-structured glass used in full-wave simulations). FIG. 14C illustrates refractive index distribution along the plane of the smart window. The upper panel of FIG. 14D illustrates refractive index distribution along a vertical cross-section of the smart window. The lower panel illustrates simulated spatial distribution of optical absorption (i.e., product of electric field component of light and imaginary part of the complex optical refractive index). In some embodiments, the randomness of the nano-structure can be controlled so that the feature sizes of the random nano-structures are subwavelength to prevent excessive scattering of sunlight, which would cause haze, and that the nano-structured SNO 1408 supports local optical resonances so that when SNO is in the opaque state, it could strongly absorb sunlight in localized hot spots, as illustrated in FIG. 14D. Full-wave simulations shown in FIG. 14E indicate that when SNO 1408 is in the pristine or optically opaque state, the smart-window 1400 has a transmissivity of no more than 10% over the entire solar spectrum (consisting of the UV, visible, and near-infrared), whereas when SNO 1408 is in the electron-doped or optically transparent state, the smart-window has an averaged transmissivity of ˜70% in the solar spectrum. Five spectra for each state are shown, which are the results of simulations of five different geometries generated with the same randomization parameters (i.e., RMS amplitude and correlation length of surface roughness).

Emissivity represents the ability of a surface to radiate heat compared to that of a black body at the same temperature. Based on Kirchhoff's law of thermal radiation, emissivity is equal to absorptivity, which equals to 1−reflectivity−transmissivity. Tunable emissivity can be beneficial for use in a wide variety of applications, including but not limited to, spacecraft. Variable emissivity coatings have long been considered as a technology to regulate the temperatures of spacecrafts, as thermal radiation is the only substantial mechanism involved in heat transfer in a vacuum. Spacecraft thermal control can be achieved using mechanical or electrostatic louvers, which can have certain disadvantages, such as bulkiness, moving components, and high weight. As a result, such devices can be unsuitable for use in micro-spacecraft and energy-intensive large manned spacecraft. Thermal radiation is also an important energy transfer mechanism in ambient conditions, especially when the temperature difference between the object with high temperatures (e.g., buildings, vehicles, people) and the surrounding environment is large, because net radiative energy transfer is proportional to T_{obj}⁴−T_{sky}⁴, where the radiative temperature of a clear sky with low humidity can be as low as T_{sky}=−40° C. Variable emissivity coatings that provide a large tuning range of emissivity in the infrared spectrum can be an effective means of thermoregulation.

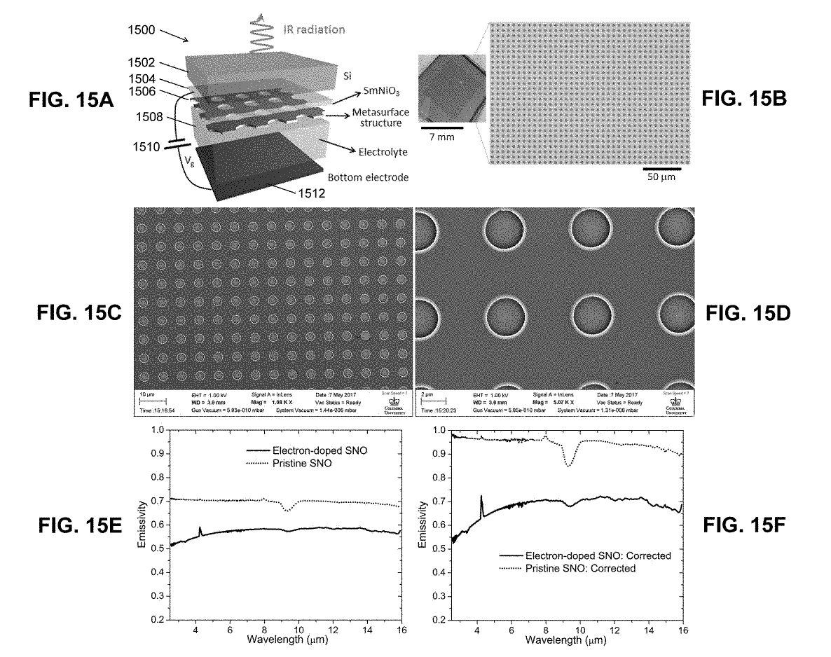

In accordance with the disclosed subject matter, designs and experimental demonstrations of variable emissivity coatings based on SNO are provided. FIG. 15A illustrates an exemplary variable emissivity coating 1500 based on a plasmonic hole array 1506, which can modulate the amount of thermal radiation emitted from the top cover layer 1502 of the device. A silicon thin film is used as the top cover layer 1502 as an example. But any thin films sufficiently transparent in the infrared can be used as the top cover layer, including thin layers of MgF₂, CaF₂, BaF₂, polymers, and air. The plasmonic hole array 1506 patterned on SNO 1504 has a square lattice ranging from 5 to 10 microns and the size of holes ranges from 2 to 3 microns. FIG. 15B shows photos of a gold plasmonic hole array patterned on an SNO film. FIGS. 15C-15D are SEM images showing the plasmonic hole array and the underlying SNO film. FIG. 15E shows tunable emissivity spectra measured from a device consisting of a plasmonic hole array and 200-nm SNO. Tuning of thermal emissivity Δ∈ is approximately 0.1 in this device, when SNO is switched between the pristine and electron-doped states. The silicon-air interface on the surface of the device 1500 reduces measurable tuning of thermal emissivity. FIG. 15F shows that the intrinsic tuning of thermal emissivity provided by the device 1500, removing the effects of the silicon-air interface on the surface of the device, is Δ∈˜0.2.

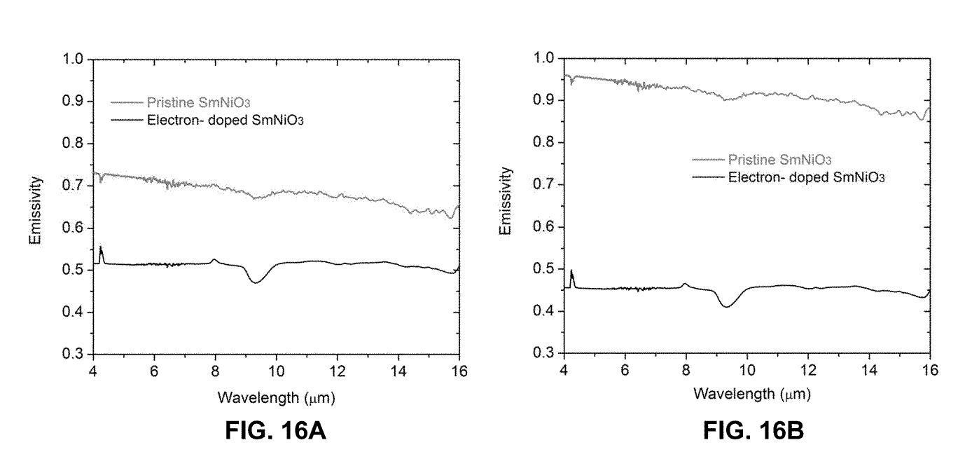

FIG. 16A shows tunable emissivity spectra measured from a device 1500 consisting of a plasmonic hole array and 500-nm SNO. Tuning of thermal emissivity Δ∈ realized in this device is about 0.18 (weighted by thermal radiation spectrum at T=27° C. between λ=4 to 16 μm), when SNO is switched between the pristine and electron-doped states. FIG. 16B shows that the intrinsic tuning of thermal emissivity provided by the device 1500, removing the effects of the silicon-air interface on the surface of the device, is Δ∈˜0.45.

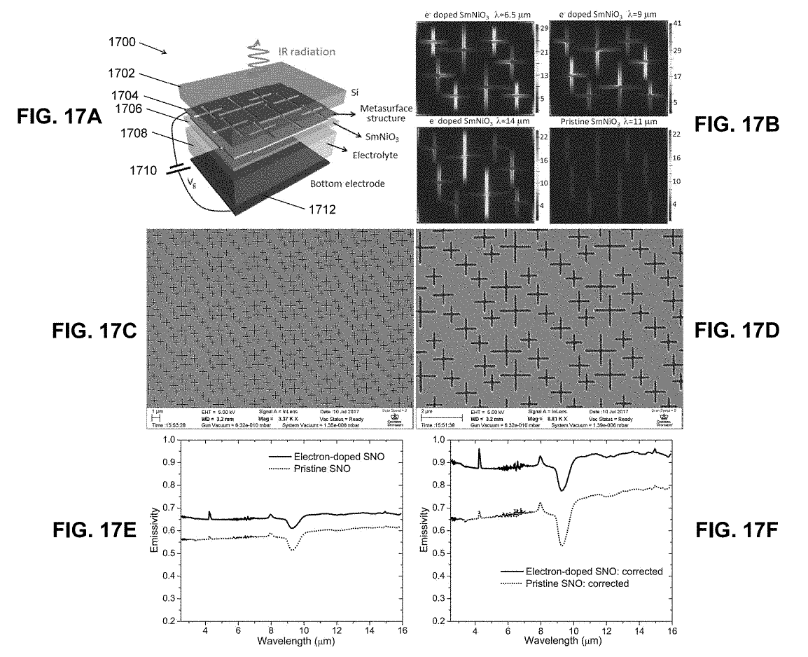

FIG. 17A is a schematic diagram illustrating another exemplary embodiment of variable emissivity coating 1700 that is based on an array of cross-shaped plasmonic apertures 1704, and can modulate the amount of thermal radiation emitted from the top cover layer 1702 of the device. In some embodiments, a silicon thin film is used as the top cover layer 1702. In some embodiments, any thin films sufficiently transparent in the infrared can be used as the top cover layer, including thin layers of MgF₂, CaF₂, BaF₂, polymers, and air. FIG. 17B illustrates simulation results showing that when SNO is in the electron-doped or optically transparent state, cross aperture antennas of different sizes are resonant at different wavelengths (first three panels), forming a uniformly large infrared absorptivity or emissivity spectrum. When SNO is in the pristine or opaque state, the plasmonic resonance is damped (last panel), leading to high infrared reflection, or reduced thermal emissivity. FIGS. 17C-17D show SEM images of a variable emissivity coating with cross aperture antennas. Shown is the step of the device fabrication where the cross aperture antennas 1704 are patterned on a silicon wafer 1702 using electron-beam lithography, before the deposition of SNO thin films 1706. The antennas 1704 consist of 5-nm of Cr and 50-nm of Pt. FIG. 17E shows measured performance of a device when SNO is at the pristine and electron-doped states, showing tuning of thermal emissivity Δ∈ of ˜0.1 (weighted by thermal radiation spectrum at T=25° C. between λ=2.5 to 16 μm). The thickness of SNO is 200 nm. The silicon-air interface on the surface of the device reduces measurable tuning of thermal emissivity. FIG. 17F shows that the intrinsic tuning of thermal emissivity provided by the device 1700, removing the effects of the silicon-air interface on the surface of the device, is Δ∈˜0.2.

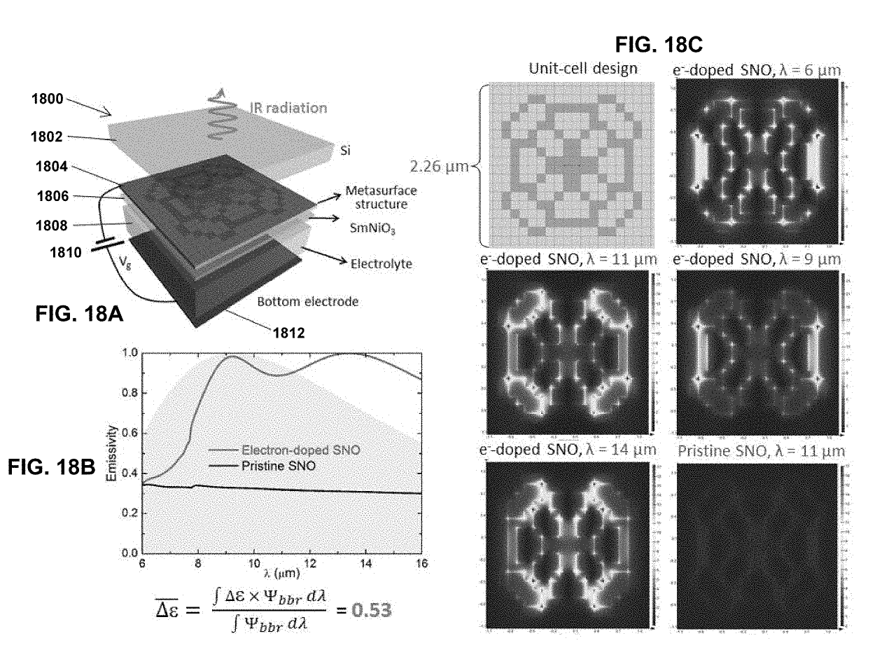

FIG. 18A is a schematic diagram illustrating another exemplary variable emissivity coating 1800 that is based on a binary metasurface 1804. The binary metasurface 1804 is created using inverse design techniques, such as binary search algorism and genetic algorism, to create maximize the tunability of emissivity. In one example shown in FIG. 18A, a binary search algorism is applied to a square unit cell that comprises the metasurface. The square with a lateral size of 2.26 μm is divided into 18×18 pixels, which can be filled with gold or air. The optimized design and its performance are shown in FIG. 18C illustrating a schematic of the unit cell of the metasurface and near-field distributions at several mid-infrared wavelengths. When SNO 1806 is in its electron-doped or optically transparent state, incident infrared waves of different wavelengths excite different plasmonic modes in the unit cell; this leads to broadband infrared absorption and thus high emissivity in the mid-infrared (since thermal radiation and emission are reciprocal processes). When SNO 1806 is in the pristine or optically lossy state, all plasmonic modes of the metasurface are damped. The metasurface now functions as a mirror for the incident thermal radiation: reflectivity is high in the mid-infrared and correspondingly the thermal emissivity is low. FIG. 18B shows that the device 1800 can provide a tuning of thermal emissivity Δ∈=0.53, according to full-wave simulations, which is larger than the amount of tuning provided by variable emissivity coatings shown above, which are based on “forward” design principles.

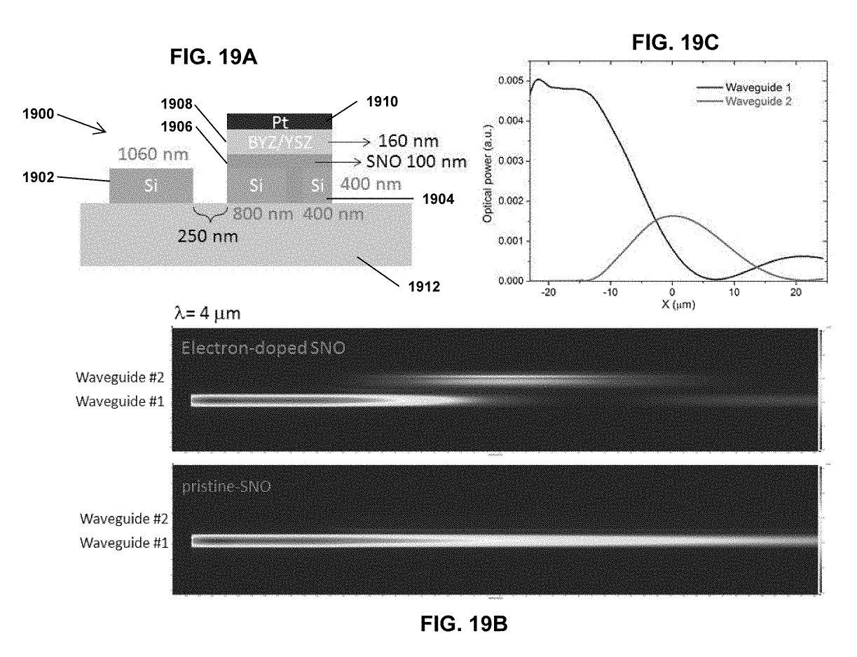

As discussed above, SNO can be used in integrated photonic devices. FIG. 19A shows a schematic of the cross-section of a tunable directional coupler 1900 based on SNO. The directional coupler consists of a passive Si waveguide 1902 and an active notched Si waveguide 1904 with the notch loaded with SNO 1906. The transverse-electric (TE) fundamental waveguide mode (E-field parallel to the device substrate) has its power concentrated in the notch and thus the interaction between light and SNO is enhanced. FIG. 19B shows full-wave simulations of the device performance when SNO is switched between its two states via ion and electron injection by ceramic heterojunctions 1908 consisting of BYZ/YSZ.

Specifically, full-wave simulations show that when SNO is in the electron-doped state (FIG. 19C), light first launched into the passive waveguide as the TE fundamental waveguide mode couples into the active waveguide as the TE fundamental mode after propagating over a distance of ˜15 microns. The inverse process occurs during the next ˜15-micron propagation distance. However, when SNO is in its pristine or optically lossy state, light can stay in the passive waveguide indefinitely. The overall decay of the intensity of light propagating along the waveguides is due to absorption in the SNO because its optical extinction coefficient is non-zero at both states. FIG. 19C illustrates the distribution of optical intensity along the two waveguide branches of the device when SNO is in the electron-doped or optically transparent state, showing that optical power is coupled back and forth between waveguides #1 and #2.

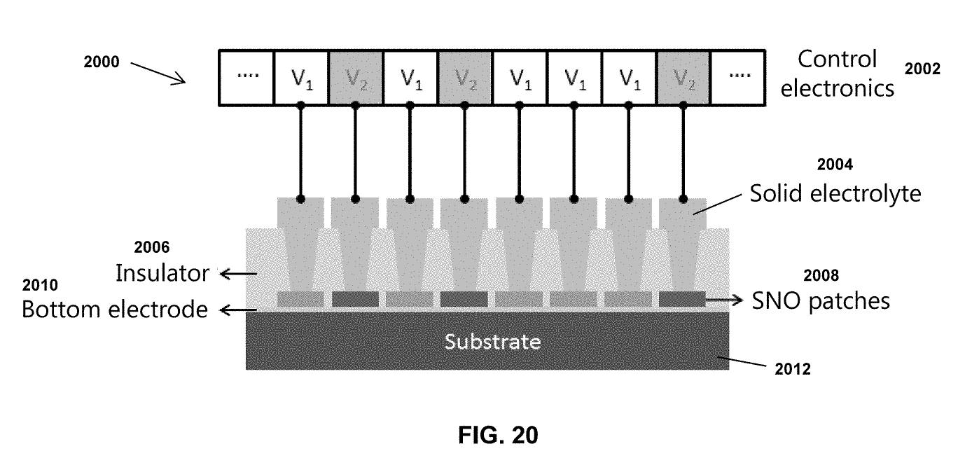

As discussed above, SNO can be used in optical memory devices and spatial light modulators. FIG. 20 shows a schematic of such devices 2000 that are based on arrays of SNO patches 2008 disposed proximate a bottom electrode 2010 and substrate 2012. An array of solid electrolyte electrodes 2004 can apply an array of voltages to the arrays of SNO patches 2008 through a control electronic circuit 2002. In this way, the SNO patches 2008 can be electron-doped by various degrees, leading to a spatial distribution of optical transmissivity or reflectivity. Such spatial modulation of the optical properties can be used to record information as in the application of optical memory, or can be used to mold a flat incident optical wavefront into desired shapes as in the application of a spatial light modulator.

Perovskite nickelates as a platform for photonics according to the disclosed subject matter can provide several advantages, including and without limitation, that the phase change of SNO can be induced by filling-controlled Mott transition and there is no crystal symmetry change during the phase-transition process. For purpose of illustration and comparison, structural symmetry breaking occurs in the thermal phase transitions of nickelates and VO₂, and switching between amorphous and crystalline states occurs in phase-change chalcogenide alloys. Fast switching between the two phases of SNO can be performed at speeds up to the speed of carrier injection and removal. A switching time ranging from seconds to minutes can occur in SNO films a couple hundred nanometers in thickness. The operation speed can be boosted by using nanometer thick SNO films, and large optical modulation depth can still be achieved by using metasurface structures to enhance the interaction between light and small volumes of SNO. As such, SNO can be used in planar optical modulators and spatial light modulators that allow for molding optical wavefronts in time and in space.

Another advantage of using perovskite nickelates for photonics according to the disclosed subject matter is that the phase transition of SNO can be induced by electron doping at room temperature. In addition, high-quality SNO thin films can be reliably synthesized and are stable in ambient conditions. These properties make the material suitable for electric-field tunable solid-state devices and compare favorably to other tunable optical materials where light, temperature, or magnetic field, instead of electric field, is used to change the materials properties. These properties also compare favorably to organic electrochromic materials and some inorganic electrochromic materials (such as Li₄Ti₅O₁₂) that are relatively unstable in the presence of oxygen and moisture.

A further advantage of perovskite nickelates as a platform for photonics according to the disclosed subject matter is that the optically opaque and transparent states of SNO can be highly stable, non-volatile, and its intermediate states with various degrees of transparency can be addressed reversibly by controlling the level of doping. The non-volatile, multilevel optical states of SNO can be utilized to create reconfigurable, low power planar photonic devices, such as programmable holograms and optical memories.

An additional advantage of perovskite nickelates as a platform for photonics according to the disclosed subject matter is that strong electron correlation as a result of electron doping in SNO can significantly open the optical band gap, and produce a substantial change in its optical refractive indices over an exceptionally broad spectrum, from the visible to the long-wavelength mid-infrared, as shown for example in FIG. 1F. This property can allow for improved tuning of optical reflectivity and transmissivity in terms of modulation depth and bandwidth. The improved broadband performance of SNO and its second-to-minute level phase-transition time can be utilized, for example and without limitation, for applications in smart windows and variable emissivity coatings.

The foregoing merely illustrates the principles of the disclosed subject matter. Various modifications and alterations to the described embodiments will be apparent to those skilled in the art in view of the teachings herein. It will be appreciated that those skilled in the art will be able to devise numerous modifications which, although not explicitly described herein, embody its principles and are thus within its spirit and scope.

What is claimed is:

1. A smart window, comprising:
a transparent material; and
an active photonic device disposed along the transparent material, the active photonic device comprising:
a thin film of perovskite material disposed proximate the transparent material,
a proton barrier disposed proximate the thin film,
a proton reservoir disposed proximate the proton barrier, and
a metal grating disposed proximate the proton reservoir.

2. The smart window of claim 1, wherein the metal grating comprises platinum or palladium.

3. The smart window of claim 1, wherein the perovskite material comprises samarium nickelate.

4. The smart window of claim 1, wherein the proton barrier comprises yttria-stabilized zirconia.

5. The smart window of claim 1, wherein the proton reservoir comprises yttrium-doped barium zirconate.

6. A variable emissivity coating, comprising:
a metallic substrate;
an electrically-insulative layer disposed proximate the metallic substrate; and
an active photonic device disposed proximate the electrically-insulative layer, the active photonic device comprising a thin film of perovskite material.

7. The variable emissivity coating of claim 6, wherein the metallic substrate comprises platinum.

8. The variable emissivity coating of claim 6, wherein the electrically-insulative layer has a high thermal conductivity.

9. The variable emissivity coating of claim 8, wherein the electrically-insulative layer comprises aluminum oxide.

10. The variable emissivity coating of claim 6, wherein the perovskite material comprises samarium nickelate.

11. A variable emissivity coating comprising:
a bottom electrode;
an electrolyte layer disposed over the bottom electrode;
a plasmonic metasurface layer disposed over the electrolyte layer;
a layer of perovskite material disposed over the plasmonic metasurface; and
a top cover layer.

12. The variable emissivity coating of claim 11, wherein the electrolyte layer metallic substrate comprises a liquid electrolyte.

13. The variable emissivity coating of claim 12, wherein the liquid electrolyte comprises a solution of water and KOH.

14. The variable emissivity coating of claim 11, wherein the electrolyte layer metallic substrate comprises a solid electrolyte.

15. The variable emissivity coating of claim 14, wherein the solid electrolyte comprises a solid polymer electrolyte containing a mixture of bis(trifluoromethane)sulfonamide lithium salt (LiTFSI), and poly(ethylene glycol) (PEG) platinum.

16. The variable emissivity coating of claim 11, wherein the plasmonic metasurface layer comprises a metallic hole array.

17. The variable emissivity coating of claim 11, wherein the plasmonic metasurface layer comprises a cross aperture antenna array.

18. The variable emissivity coating of claim 11, wherein the plasmonic metasurface layer comprises a binary metallic structure created using inverse design techniques.

19. The variable emissivity coating of claim 18, wherein the inverse design techniques are selected from a group consisting of a binary search algorism and genetic algorism.

20. The variable emissivity coating of claim 11, wherein the perovskite material comprises samarium nickelate.

21. The variable emissivity coating of claim 11, wherein the top cover layer is transparent in the infrared.

22. The variable emissivity coating of claim 21, wherein the top cover layer is selected from the group consisting of: MgF₂, CaF₂, BaF₂, polymers, and air.

23. An optical memory device comprising an active photonic device, the active photonic device, comprising:
a substrate;
a membrane disposed proximate and suspended by the substrate;
a thin film of perovskite material disposed proximate the membrane; and
a metal grating disposed proximate the thin film.

24. The optical memory device of claim 23, wherein the substrate comprises silicon.

25. The optical memory device of claim 23, wherein the membrane comprises silicon nitride.

26. The optical memory device of claim 23, wherein the perovskite material comprises samarium nickelate.

27. The optical memory device of claim 23, wherein the metal grating comprises platinum.

28. A metasurface modulator, comprising:
a mirror;
an insulating layer disposed proximate the mirror;
a thin film of perovskite material disposed proximate the insulating layer; and
an aperture antenna disposed proximate the thin film.

29. The metasurface modulator of claim 28, wherein the mirror comprises platinum.

30. The metasurface modulator of claim 28, wherein the insulating layer comprises silicon dioxide.

31. The metasurface modulator of claim 28, wherein the perovskite material comprises samarium nickelate.

32. The metasurface modulator of claim 28, wherein the aperture antenna has a cross-shaped aperture defined therein.

33. The metasurface modulator of claim 28, wherein the aperture antenna comprises platinum.

34. A solid-state electro-optic modulator, comprising:
a substrate;
a thin film of perovskite material disposed proximate the substrate;
a solid polymer electrolyte disposed proximate the thin film;
an electrode disposed proximate the solid polymer electrolyte.

35. The solid-state electro-optic modulator of claim 34, wherein the perovskite material comprises samarium nickelate.

36. The solid-state electro-optic modulator of claim 34, wherein the solid polymer electrolyte comprises polyethylene glycol.

37. The solid-state electro-optic modulator of claim 34, wherein the solid polymer electrolyte comprises lithium ions.

38. The solid-state electro-optic modulator of claim 34, wherein the electrode comprises lithium cobalt oxide.
